(19) United States
(12) Patent Application Publication
(10) Pub. No.: US 2016/0240411 A1
(43) Pub. Date: Aug. 18, 2016

(54) MULTI-PROCESSING APPARATUS AND METHOD FOR MANUFACTURING SEMICONDUCTOR DEVICE

(71) Applicant: KABUSHIKI KAISHA TOSHIBA, Tokyo (JP)

(72) Inventors: Takeharu MOTOKAWA, Zushi (JP); Kazuki HAGIHARA, Kawasaki (JP); Shuichi TANIGUCHI, Yokohama (JP)

(21) Appl. No.: 14/843,545

(22) Filed: Sep. 2, 2015

(30) Foreign Application Priority Data
Feb. 18, 2015 (JP) 2015-029910

(51) Int. Cl. H01L 21/67; H01J 37/32

(52) U.S. Cl. CPC H01L 21/67213; H01L 21/67069; H01L 21/6719; H01L 21/67167; H01J 37/32743; H01J 37/32899; H01J 2237/334

(57) ABSTRACT

A multi-processing apparatus includes an electron beam irradiation unit, a dry etching unit and a transfer unit. The transfer unit is connected to the electron beam irradiation unit and the dry etching unit, and is configured to transfer a wafer under a reduced-pressure atmosphere from the electron beam irradiation unit to the dry etching unit.

### CROSS-REFERENCE TO RELATED APPLICATIONS

This application is based upon and claims the benefit of priority from Japanese Patent Application No. 2015-029910, filed on Feb. 18, 2015; the entire contents of which are incorporated herein by reference,

### FIELD

Embodiments described herein relate generally to a multi-processing apparatus and a method for manufacturing a semiconductor device.

### BACKGROUND

Highly-integrated semiconductor devices are manufactured by the use of a thin resist mask that is advantageous to form fine patterns. The thin resist is preferably subjected to plasma irradiation or electron beam irradiation in order to improve etching resistance property thereof, However, the resist mask may exhibit degradation of the property, when being exposed to the air just after the plasma irradiation or electron beam irradiation.

### BRIEF DESCRIPTION OF THE DRAWINGS

FIG, 1 is a schematic view showing a multi-processing apparatus according to a first embodiment;

FIG. 2 is a flowchart showing a dry etching method according to the first embodiment;

FIGS. 3A to 3D are schematic cross-sectional view showing a dry etching process according to the first embodiment;

FIG. 4 is a flowchart showing a dry etching method according to a second embodiment; and

FIGS. 5A to 5F are schematic cross-sectional view showing a dry etching process according to the second embodiment.

### DETAILED DESCRIPTION

According to an embodiment, a multi-processing apparatus includes an electron beam irradiation unit, a dry etching unit and a transfer unit. The transfer unit is connected to the electron beam irradiation unit and the dry etching unit, and is configured to transfer a wafer under a reduced-pressure atmosphere from the electron beam irradiation unit to the dry etching unit.

Embodiments will now be described with reference to the drawings, The same portions inside the drawings are marked with the same numerals; a detailed description is omitted as appropriate; and the different portions are described, The drawings are schematic or conceptual; and the relationships between the thicknesses and widths of portions, the proportions of sizes between portions, etc., are not necessarily the same as the actual values thereof, The dimensions and/or the proportions may be illustrated differently between the drawings, even in the case where the same portion is illustrated,

### First Embodiment

FIG. 1 is a schematic view showing a multi-processing apparatus 1 according to a first embodiment, The multi-processing apparatus 1 includes an electron beam irradiation unit 10, a dry etching unit 20, and a plasma irradiation unit 30. The multi-processing apparatus may sequentially carry out a plurality of manufacturing processes. The multi-processing apparatus 1 further includes a transferring unit 40, and the electron beam irradiation unit 10. The dry etching unit 20 and the plasma irradiation unit 30 are respectively connected to the transferring unit 40.

The transferring unit 40 includes e.g. a carrying robot 41 and transfers a wafer 43 from one of the units to the other. The carrying robot 41 has a main body 45 and a robot arm 47. The main body is capable of making a 360 turn, for example. Further, the transferring unit 40 transfers the wafer 43 between the respective units under reduced pressure. The interior of the transferring unit 40 is held at pressure of e.g. 10 Pa or less, Thereby, water may be evaporated from a resist mask formed on the surface of the wafer 43. The oxygen concentration within the transferring unit 40 is held at 20 ppm or less.

The multi-processing apparatus 1 further includes a gate unit 50, temperature adjustment units 60, 70, and a control unit 80. The wafer 43 is carried through the gate unit 50 from outside into the transferring unit 40 that is under reduced pressure, and the wafer 43 is carried out from the gate unit 50 after being processed. That is, the wafer 43 is carried in and carried out from the multi-processing apparatus 1 without breaking the reduced-pressure state of the transferring unit 40 by the use of the gate unit 50. The temperature adjustment units 60, 70 hold the wafer 43 at a predetermined temperature. The temperature adjustment units 60, 70 makes it possible to omit wafer heating or cooling, for example, in the electron beam irradiation unit 10 and the plasma irradiation unit 30. Thereby, the processing time in each unit may be shorter than that in an apparatus without a temperature adjustment unit. The control unit 80 sends commands to a controller of each unit and executes the multi-processing, as will be described later.

Next, a configuration of the multi-processing apparatus 1 will be explained in detail with reference to FIG. 1.

The electron beam irradiation unit 10 includes a wafer stage 11, an electron-beam gun 13, a voltage control device 15, an isolation wall 17, and a controller 19. The controller 19 controls the electron-beam gun 13 to irradiate the wafer 43 placed on the wafer stage 11 with an electron beam, Further, the controller 19 controls the potential of the wafer stage 11 using the voltage control device 15,

It is favorable that the wafer stage 11 is electrically connected to the wafer 43. For example, the wafer stage 11 may include a connection conductor that is capable of being in contact with at least a part of the wafer 43. Thereby, no potential difference is induced between the wafer stage 11 and the wafer 43.

The wafer stage 11 may be at the ground potential or a potential set by the voltage control device 15. The potential of the wafer stage 11 is set to e.g. −4000 V. Negative potential set to the wafer stage 11 makes it possible to monitor the secondary electrons emitted by electron beam irradiation.

Further, the negative potential induces a decelerating electric field for incident electrons toward the wafer stage 11 and an accelerating electric field for electrons emitted therefrom.

Thus, the negative potential may reduce the influence of charges in the wafer 43. When the influence of charges in the wafer 43 is small, the wafer stage 11 may be set to have positive potential for accelerating the incident electrons. Furthermore, the wafer stage 11 contains at least one of a heater and a cooling element, and holds the wafer 43 at a predetermined temperature. For example, the wafer temperature is held at an arbitrary temperature within a temperature range from −40° C. to 290° C. The electron-beam gun 13 includes an electron beam source of e.g. a hot cathode, a photocathode, a field emission cathode, or the like. The electron beam source may be preferably selected depending on the area and the dose amount of electron beam irradiation. For example, a hot cathode of lanthanum boride (LaB₆) may be selected.

The isolation wall 17 electrically isolates the electron beam irradiation unit 10 from the transferring unit 40 and other units, That is, the isolation wall 17 may block the electrical noise from other units to achieve a stable operation of the electron-beam gun 13. The isolation wall 17 is a connecting body made of e.g. a dielectric material, which is provided between the electron beam irradiation unit and the transferring unit 40. Further, the isolation wall 17 includes a gate valve between the electron beam irradiation unit 10 and the transferring unit 40.

The controller 19 communicates with the control unit 80 via e.g. an optical communication module 81. That is, the electron beam irradiation unit 10 is also electrically isolated from the control unit 80. Thus, it is possible to block the electrical noise from the other units via the control unit 80 to achieve the stable operation of the electron-beam gun 13. Note that the optical communication module 81 may be e.g. a photo-coupler. Alternatively, the optical communication module comprises a system which includes optical transceivers provided in each of the controller 19 and the control unit 80, and an optical fiber connected to the optical transceivers.

Further, the electron beam irradiation unit 10 may have a function for protecting the electron beam irradiation system from temperature change or composition change in atmosphere. For example, the electron beam irradiation unit 10 may comprises a temperature regulation system. Specifically, the controller 19 may adjust a temperature inside the electron beam irradiation unit 10 using a heater or a cooling device provided therein. The controller 19 may monitor e.g. an oxygen concentration inside the electron beam irradiation unit 10 using an atmosphere monitor, and control the pressure therein using a vacuum pump (not shown).

The dry etching unit 20 includes a wafer stage 21, a high-frequency power source 22, a pressure control device 23, a mass flow controller 25, and a controller 27. The controller 27 fills the dry etching unit 20 with an atmosphere containing an etching gas at predetermined pressure, using the pressure control device 23 and the mass flow controller 25. Then, the controller 27 excites plasma between the wafer 43 placed on the wafer stage 21 and an electrode (not shown) using the high-frequency power source 22, thereby etching a surface of the wafer 43.

The dry etching unit 20 includes a gate valve 29 between the transferring unit 40 and itself. The controller 27 opens and closes the gate valve 29. The carrying robot 41 places the wafer 43 on the wafer stage 21 and takes the wafer from the wafer stage 21 through the gate valve.

The plasma irradiation unit 30 includes a wafer stage 31, a high-frequency power source 32, a pressure control device 33, a mass flow controller 35, and a controller 37. The controller 37 sends commands to the pressure control device 33 and the mass flow controller 35 to fill the interior of the plasma irradiation unit 30 with an inert gas at predetermined pressure. Then, the controller 37 excites plasma between the wafer 43 placed on the wafer stage 31 and an electrode (not shown) using the high-frequency power source 32, thereby exposing the surface of the wafer 43 to the plasma.

The condition of plasma excitation is preferably selected depending on a resist to be reformed. For example, when reforming a region limited to an extremely thin surface layer of the resist, an inert gas such as nitride or argon is preferably used. When reforming over a deeper region from the surface of the resist, a sedimentary gas such as methane or perfluorocyclobutane may be used.

The plasma irradiation unit 30 further includes a gate valve 39 between the transferring unit 40 and itself. The controller 37 opens and closes the gate valve 39. The carrying robot 41 places the wafer 43 on the wafer stage 31 and takes the wafer from the wafer stage 31 through the gate valve 39.

The temperature adjustment unit 60 includes a wafer stage 61, a controller 63, and an isolation wall 67. The controller 63 may hold the wafer stage 61 at a predetermined temperature using e.g. a heater or cooling device (not shown) that is provided in the wafer stage 61.

The isolation wall 67 thermally isolates the transferring unit 40 from the temperature adjustment unit 60. That is, the isolation wall 67 is a connecting body made of a heat insulating material provided between the transferring unit 40 and the temperature adjustment unit 60. Further, the isolation wall 67 includes a gate valve that provides a pathway between the transferring unit 40 and the temperature adjustment unit 60.

The temperature adjustment unit 70 includes a wafer stage 71, a controller 73, and an isolation wall 77. The controller 73 holds the wafer stage 71 at a predetermined temperature using e.g. a heater or cooling device (not shown) contained in the wafer stage 71.

The isolation wail 77 thermally isolates the transferring unit 40 from the temperature adjustment unit 70. That is, the isolation wall 77 is a connecting body containing heat insulating material. Further, the isolation wall 77 includes a gate valve that makes a pathway between the transferring unit 40 and the temperature adjustment unit 70.

The gate unit 50 includes a wafer stocker 51 and a controller 53. The wafer stocker 51 temporarily holds the wafer 43 that is carried into the gate unit 51 from the outside or the wafer 43 after processing. The controller 53 controls a gale 55, a gate valve 56 and a vacuum pump (not shown) when carrying the wafer 43 in the transferring unit 40 and carrying out the wafer 43 therefrom. The gate 55 is provided between the outside and the gate unit 50. The gate valve 56 is provided between the transferring unit 40 and the gate unit 50. The controller 53 sequentially opens and closes the gate 55 and the gate valve 56, and controls the internal pressure of the gate unit 50 by using the vacuum pump. Thus, it may be possible to perform the carry-in and carry-out processes of the wafer 43 without breaking the reduced-pressure state in the transferring unit 40.

Further, the gate unit 50 may include a neutralization device 57. The neutralization device 57 irradiates the wafer 43 with a soft X-ray, for example, under atmospheric pressure to remove charges therefrom. Alternatively, the neutralization device 57 may generate corona discharge in the gate unit 50 for removing charges from the wafer 43.

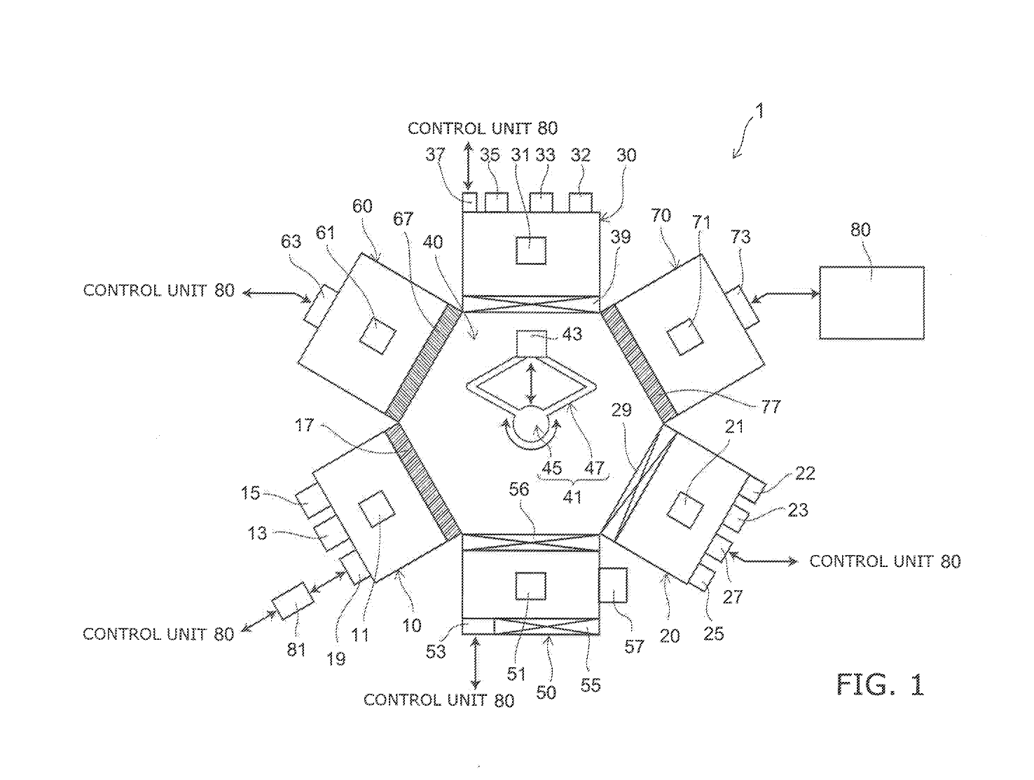

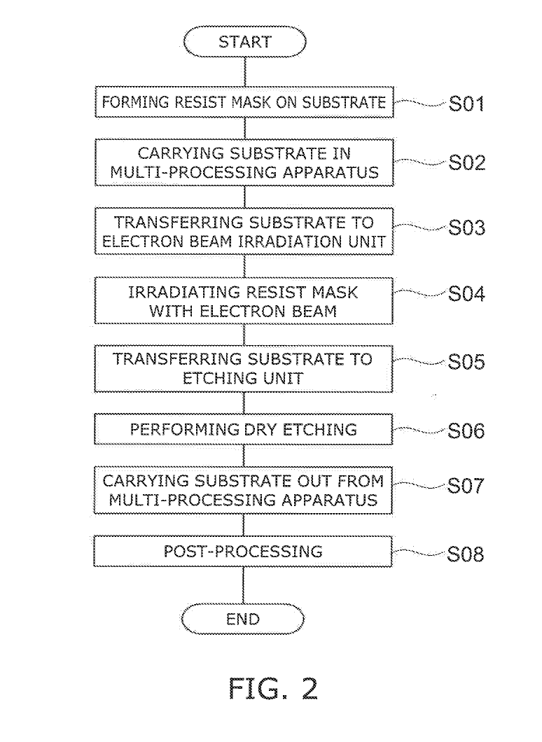

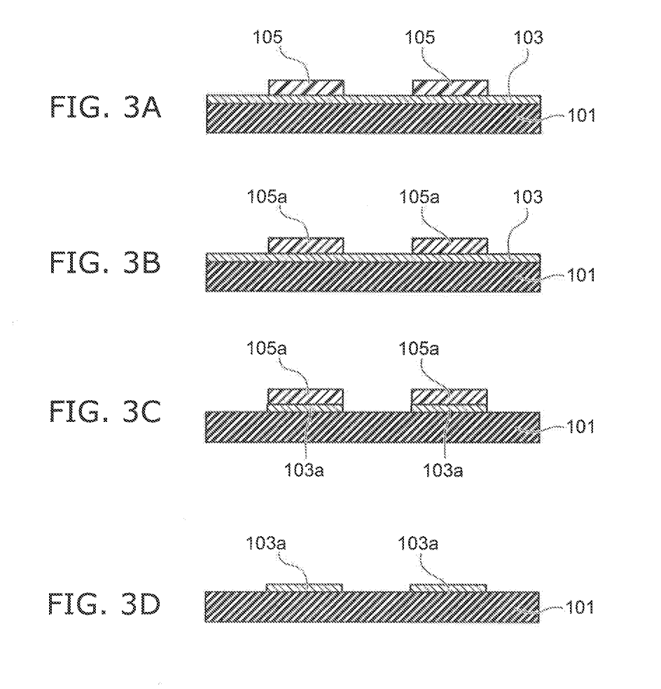

Next, a dry etching method using the multi-processing apparatus 1 will be explained with reference to FIGS. 1, 2, and 3A to 3D. FIG. 2 is a flowchart showing a dry etching method according to the first embodiment. In this example, a quartz substrate 101 is used as the wafer 43. FIGS. 3A to 3D are schematic views showing a cross-section of the quartz substrate 101 at each step of the dry etching process.

Step S01: forming resist masks 105 on the quartz substrate 101. As shown in FIG. 3A, a chromium (Cr) film 103 is formed on the quartz substrate 101. For example, a chemical amplification type resist having a thickness of 30 nanometers (nm) or less is applied onto the chromium film 103, then, photolithography processes such as exposing, baking, and developing are performed to form the resist masks 105 on the chromium film 103. These processes are performed outside the multi-processing apparatus 1.

Step S02: carrying the quartz substrate 101 into the multi-processing apparatus 1. For example, the controller 53 of the gate unit 50 receives a command from outside or the control unit 80, sets the interior of the gate unit 50 at atmospheric pressure, and opens the carry-in gate 55. Then, the controller 53 closes the gate 55 and reduces pressure within the gate unit 50, when receiving a signal that indicates the quartz substrate 101 being placed on the wafer stocker 51.

Step S03: transferring the quartz substrate 101 from the gate unit 50 to the electron beam irradiation unit 10. For example, when the internal pressure of the gate unit 50 becomes the same as the internal pressure of the transferring unit 40 or lower than the internal pressure of the transferring unit 40, the controller 53 opens the gate valve 56 on the transferring unit 40 side of the gate unit 50 and sends a signal to the control unit 80.

When receiving the signal from the controller 53, the control unit 80 sends a command to the carrying robot 41 for taking out the quartz substrate 101 from the gate unit 50. Then, the carrying robot 41 takes out the quartz substrate 101 from the wafer stocker 51, and sends a signal to the control unit 80.

When receiving the signal that indicates the quartz substrate 101 being taken out from the wafer stocker 51, the control unit 80 sends a command to the controller 53 to close the gate valve 56. Further, the control unit 80 sends a command to the controller 19 of the electron beam irradiation unit 10 to open the gate valve communicating with the transferring unit 40, The controller 19 sends a signal to the control unit 80, which indicates the gate valve being opened.

When receiving the signal from the controller 19, the control unit 80 sends a command to the carrying robot 41 to place the quartz substrate 101 on the wafer stage 11. The carrying robot 41 sends a signal to the control unit 80, which indicates the quartz substrate 101 being placed on the wafer stage 11.

Step S04: irradiating the resist masks 105 on the quartz substrate 101 with an electron beam. The control unit 80 sends a command for executing electron beam irradiation to the controller 19 of the electron beam irradiation unit 10. The controller 19 closes the gate valve communicating with the transferring unit 40 and reduces the pressure within the electron beam irradiation unit 10 to predetermined pressure (10⁻⁵ Pa) or less. Then, the controller 19 sends a command to the electron-beam gun 13 to irradiate the quartz substrate 101 held on the wafer stage 11 with an electron beam. The electron-beam gun 13 irradiates an electron beam e.g. until the dose amount reaches 2 mC/μm². Further, it is favorable to set the accelerating voltage so that over half amount of electrons may be stopped within a depth of 30 nm from the surface.

FIG. 3B is a schematic cross-sectional view showing the quartz substrate 101 after electron beam irradiation. After the electron beam irradiation, resist masks 105a may have a lower oxygen content and higher carbon density than the resist masks 105 before electron beam irradiation. So-called “Onishi parameter” is smaller in the resist masks 105a than that in the resist masks 105, and thus, etching resistance of the resist masks 105a is improved. Note that the Onishi parameter is expressed by the following formula, and shows a degree of etching resistance.

Onishi parameter=Total number of atoms/(Number of carbon atoms−Number of oxygen atoms)

Here, the number of atoms is e.g. the number of respective elements contained in the chemical formula of the resist, and the total number of atoms is the total number of elements contained in the chemical formula.

Step S05: transferring the quartz substrate 101 from the electron beam irradiation unit 10 to the dry etching unit 20. When completing the electron beam irradiation, the controller 19 of the electron beam irradiation unit 10 opens the gate valve communicating with the transferring unit 40 and sends a signal the control unit 80, which indicates that the electron beam irradiation has been completed.

When receiving the signal from the controller 19, the control unit 80 sends a command for taking out the quartz substrate 101 from the electron beam irradiation unit 10 to the carrying robot 41. The carrying robot 41 takes out the quartz substrate 101 on the wafer stage 11 and sends a signal to the control unit 80.

When receiving the signal indicating that the quartz substrate 101 has been taken out from the electron beam irradiation unit 10, the control unit 80 sends a command to the controller 19 to close the gate valve. Then, the control unit 80 sends a command to the controller 27 of the dry etching unit 20 to open the gate valve 29 communicating with the transferring unit 40. The controller 27 sends a signal to the control unit 80, which indicates that the gate valve 29 has been opened.

When receiving the signal indicating that the gate valve 29 has been opened, the control unit 80 sends a command to the carrying robot 41 to place the quartz substrate 101 on the wafer stage 21 of the dry etching unit 20. The carrying robot 41 sends a signal to the control unit 80, which indicates that the quartz substrate 101, has been placed on the wafer stage 2L The internal pressure of the transferring unit 40 is maintained at 10 Pa or less in the transfer process during these procedures.

Step S06: selectively removing the chromium film 103 by using the resist masks 105a as shown in FIG. 3C. The control unit 80 sends a command for executing dry etching to the controller 27 of the dry etching unit 20. The controller 27 doses the gate valve 29 communicating with the transferring unit 40 and reduces the pressure within the dry etching unit 20 to predetermined pressure or less. Then, the controller 27 sends a command to the mass flow controller 25 to introduce the etching gas. Further, the controller sends a command to the pressure control device 23 to maintain the internal pressure of the dry etching unit 20 at the predetermined pressure. The controller 27 sends a command to the high-frequency power source 22 to output predetermined high-frequency power to excite plasma between e.g. the wafer stage 21 and an electrode (not shown). Then, the chromium film 103 is etched by a plasma-excited active element with an etching margin enlarged by the resist masks 105a that has the improved etching resistance.

When a predetermined etching time elapses, the controller 27 sends commands to the high-frequency power source 22 and the mass flow controller 25 to stop the high-frequency power output and the etching gas supply. Then, the controller sends a command to the pressure control device 23 to reduce the pressure within the dry etching unit 20 to pressure lower than the internal pressure of the transferring unit 40.

Step S07: carrying out the quartz substrate 101 from the multi-processing apparatus 1. The controller 27 of the dry etching unit 20 opens the gate valve 29 communicating with the transferring unit 40 and sends a signal to the control unit 80, which indicates that the dry etching has been completed.

When receiving the signal from the controller 27, the control unit 80 sends a command for taking out the quartz substrate 101 from the dry etching unit 20 to the carrying robot 41. The carrying robot 41 takes out the quartz substrate 101 on the wafer stage 21 and sends a signal to the control unit 80.

When receiving the signal indicating that the quartz substrate 101 has been taken out from the dry etching unit 20, the control unit 80 sends a command to the controller 27 to dose the gate valve 29. Then, the control unit 80 sends a command to the controller 53 of the gate unit 50 to open the gate valve 56 communicating with the transferring unit 40. The controller 53 sends a signal to the control unit 80, which indicates that the gate valve 56 has been opened.

When receiving the signal indicating that the gate valve 56 has been opened, the control unit 80 sends a command to the carrying robot 41 to place the quartz substrate 101 on the wafer stocker 51 of the gate unit 50. The carrying robot 41 sends a signal to the control unit 80, which indicates that the quartz substrate 101 has been placed on the wafer stocker 51.

When receiving the signal indicating that the quartz substrate 101 has been placed on the wafer stocker 51, the control unit 80 sends a command to the controller 53 for closing the gate valve 56, The controller 53 closes the gate valve 56, and then, returns the interior of the gate unit 50 to the atmospheric pressure and opens the carry-in gate 55 communicating with the outside.

Step S08: performing the post-processing after taking out the quartz substrate 101 from the multi-processing apparatus 1, For example, the resist masks 105a on the quartz substrate 101 are removed by oxygen aching. As shown in FIG. 3D, chromium films 103a is formed on the quartz substrate 101 with the predetermined shapes.

In the embodiment, the resist masks 105 are irradiated with the electron beam and reformed to the resist masks 105a with the improved etching resistance. Then, the quartz substrate 101 with the resist masks 105a formed thereon is transferred to the dry etching unit 20 in the reduced-pressure atmosphere at 10 Pa or less. Thereby, oxygen atoms taken into the resist masks 105a may be reduced during the transferring process; and it may be possible to avoid deterioration of the improved etching resistance. As a result, the process margin of dry etching may be enlarged, improving e.g. the dimensional accuracy of the pattern formed by etching,

### Second Embodiment

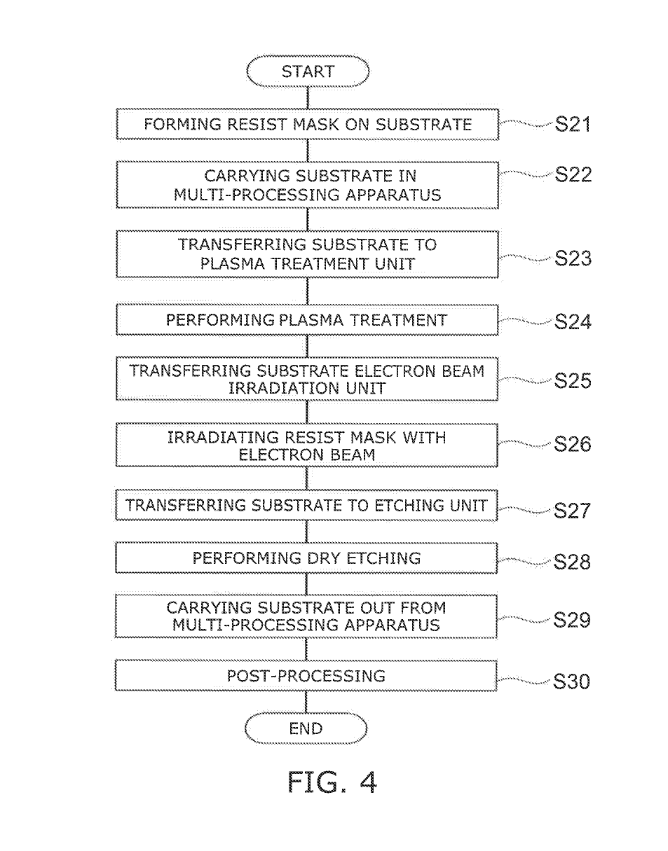

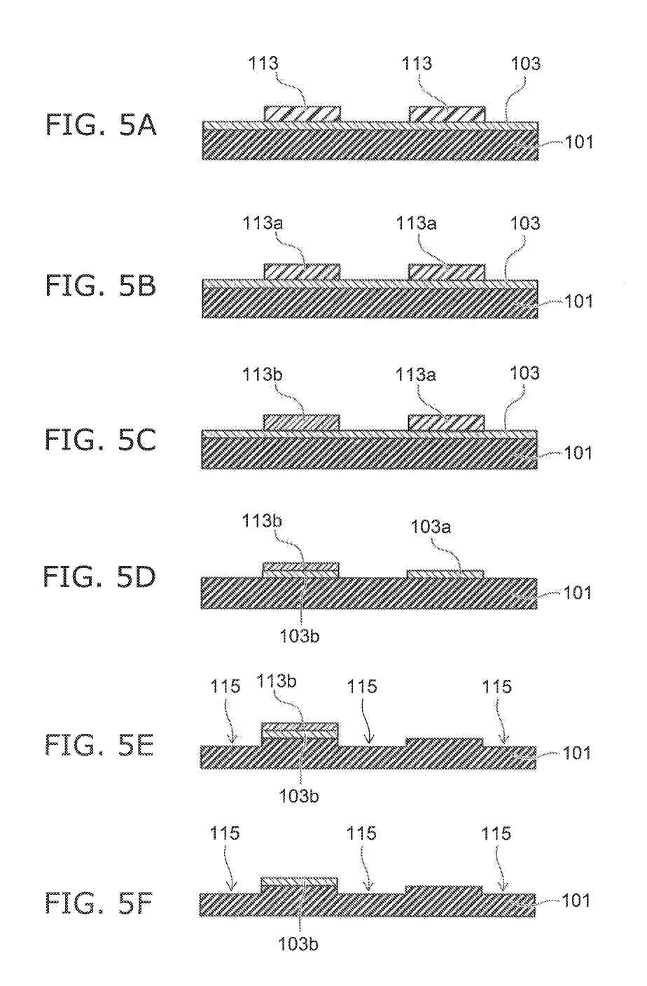

A dry etching method according to the second embodiment will be explained with reference to FIGS. 1, 4, and 5A to 5F. FIG. 4 is a flowchart showing the dry etching method according to the second embodiment, FIGS. 5A to 5F are schematic views showing a cross-section of the quartz substrate 101 in a dry etching process.

Step S21: forming resist masks 113 on the quartz substrate 101. As shown in FIG. 5A, a chromium (Cr) film 103 is formed on the quartz substrate 101. For example, a chemical amplification type resist having a thickness of 30 nanometers (nm) or less is applied onto the chromium film 103, then, the resist masks 113 are formed through the photolithography process, such as light exposure, baking, and developing processing. These processes are performed outside of the multi-processing apparatus 1.

Step S22: carrying the quartz substrate 101 with the resist masks 113 formed thereon into the multi-processing apparatus 1. For example, the control unit 80 sets the interior of the gate unit 50 at atmospheric pressure, and opens the gate 55. Then, the carry-in gate 55 is closed after the quartz substrate 101 is placed on the wafer stocker 51, and pressure within the gate unit 50 is reduced.

Step S23: transferring the quartz substrate 101 from the gate unit 50 to the plasma irradiation unit 30. For example, when the internal pressure of the gate unit 50 becomes the same as the internal pressure of the transferring unit 40 or lower than the internal pressure of the transferring unit 40, the gate valve 56 communicating with the transferring unit 40 of the gate unit 50 is opened. The carrying robot 41 takes out the quartz substrate 101 from the wafer stocker 51 and places the substrate on the wafer stage 31 of the plasma irradiation unit 30.

Step S24: exposing the resist masks 113 on the quartz substrate 101 to plasma. The controller 37 of the plasma irradiation unit 30 doses the gate valve 39 communicating with the transferring unit 40 and reduces pressure within the plasma irradiation unit 30. When the pressure within the plasma irradiation unit 30 becomes predetermined pressure or less, the controller 37 sends a command to the mass flow controller 35 for introducing a gas therein. At the same time, the controller sends a command to the pressure control device 33 for maintaining the internal pressure of the plasma irradiation unit 30 at the predetermined pressure. Further, the controller 37 sends a command to the high-frequency power source 32 for outputting predetermined high-frequency power. Thereby, plasma is excited between the wafer stage 31 and the electrode (not shown). The resist masks 113 are reformed to improve the etching resistance thereof by exposing to the plasma.

As shown in FIG. 5B, resist masks 113a after being exposed to the plasma may have e.g. higher carbon density, resulting in the smaller Onishi parameters. Thus, the etching resistance of the resist masks 113a is improved.

Step S25: transferring the quartz substrate 101 from the plasma irradiation unit 30 to the electron beam irradiation unit 10. When completing plasma irradiation, the controller 37 of the plasma irradiation unit 30 opens the gate valve 39 communicating with the transferring unit 40.

The carrying robot 41 takes out the quartz substrate 101 on the wafer stage 31 and transfers the quartz substrate 101 to the electron beam irradiation unit 10. The quartz substrate 101 is placed on the wafer stage 11 in the electron beam irradiation unit 10.

Step S26: irradiating the resist masks 113a on the quartz substrate 101 with an electron beam. The controller 19 closes the gate valve communicating with the transferring unit 40 and reduces the pressure within the electron beam irradiation unit 10 to predetermined pressure (10⁻⁵ Pa) or less. Then, the controller 19 sends a command to the electron-beam gun 13 for irradiating the quartz substrate 101 held on the wafer stage 11 with an electron beam. The electron-beam gun 13 irradiates an electron beam e.g. until the dose amount reaches 2 mC/μm². Further, it is favorable to set the accelerating voltage so that over half amount of electrons may be stopped in the surface layer within a depth of 30 nm.

FIG. 5C is a schematic cross-sectional view showing the quartz substrate 101 after the electron beam irradiation. The electron-beam gun 13 may selectively irradiates an electron beam e.g. on the quartz substrate 101. That is, the resist masks 113a and 113b are selectively formed on the quartz substrate 101. The resist mask 113b is irradiated with the electron beam, and the resist mask 113a is not irradiated with the electron beam. The resist mask 113b has e.g. lower oxygen content and a higher carbon density than those of the resist mask 113a. An Onishi parameter of the resist mask 113b is smaller than an Onishi parameter of the resist mask 113a, i.e. the etching resistance is further improved in the resist mask 113b.

Step S27: transferring the quartz substrate 101 from the electron beam irradiation unit 10 to the dry etching unit 20.

When completing the electron beam irradiation, the controller 19 of the electron beam irradiation unit 10 opens the gate valve communicating with the transferring unit 40. The carrying robot 41 takes out the quartz substrate 101 on the wafer stage 11 and transfers the substrate to the dry etching unit 20. The quartz substrate 101 is placed on the wafer stage 21.

Step S28: selectively removing the chromium film 103 using the resist masks 113a, 113b as shown in FIG. 5D. The controller 27 of the dry etching unit 20 closes the gate valve 29 communicating with the transferring unit 40 and reduces the pressure within the dry etching unit 20 to predetermined pressure or less. Subsequently, the controller 27 sends a command to the mass flow controller 25 for introducing the etching gas. Further, the controller sends a command to the pressure control device 23 for maintaining the internal pressure of the dry etching unit 20 at the predetermined pressure. The controller 27 sends a command to the high-frequency power source 22 for outputting predetermined high-frequency power to excite plasma between the wafer stage 21 and the electrode (not shown). Then, the chromium film 103 is etched by a plasma-excited active element.

When a predetermined etching time elapses, the controller 27 sends commands to the high-frequency power source 22 and the mass flow controller 25 for stopping the high-frequency power output and the etching gas supply. Then, the controller sends a command to the pressure control device 23 for reducing the pressure within the dry etching unit 20 to the pressure lower than the internal pressure of the transferring unit 40.

When the chromium film 103 is selectively etched, the resist mask 113a may be completely removed as shown in FIG. 5D, since the resist mask 113a has the lower etching resistance than that of the resist mask 113b. On the other hand, the resist mask 113b remains on chromium films 103b.

For example, the quartz substrate 101 is further etched to form recessed portions 115 on the quartz substrate 101 as shown in FIG, 5E. In this case, the chromium films 103a may be removed under a condition of etching the chromium films 103a, leaving the chromium films 103b covered by the resist masks 113b.

Step S29: carrying the quartz substrate 101 out from the multi-processing apparatus 1. The controller 27 of the dry etching unit 20 opens the gate valve 29 communicating with the transferring unit 40. The carrying robot 41 takes out the quartz substrate 101 on the wafer stage 21 and transfers the quartz substrate 101 to the wafer stocker 51 in the gate unit 50.

The controller 53 of the gate unit 50 closes the gate valve 56, returns the interior of the gate unit 50 to the atmospheric pressure, and then, opens the carry-in gate 55 communicating with the outside.

Step S30: performing the post-processing after the quartz substrate 101 is taken out from the multi-processing apparatus 1. For example, the resist masks 113b remains the quartz substrate 101 are removed by oxygen ashing. Thereby, the chromium films 103b with predetermined shapes and the recessed portions 115 are formed on the quartz substrate 101 as shown in FIG. 5E.

In this example, the control unit 80 also controls the operation of the multi-processing apparatus 1 via the controllers of the respective units. Although involvement of the control units 80 in the etching procedures is omitted in the above explanation, it is obvious that the control units send commands to the respective controllers like the steps S02 to S07 described in the first embodiment.

In the embodiment, the resist masks 113 are irradiated with plasma, and further, selectively irradiated with the electron beam. Thereby, two kinds of resist masks having different etching resistance may be formed on a substrate, and makes etching procedures being more flexibly designed. Further, the resist mask 113 may be prevented from deterioration of the improved etching resistance, since the quartz substrate 101 with the resist masks 113 formed thereon is transferred in the reduced-pressure atmosphere at 10 Pa or less. Thereby, it may be possible to enlarge the process margin of dry etching.

### Third Embodiment

The gate unit 50 of the multi-processing apparatus 1 shown in FIG. 1 may include the neutralization device 57. The neutralization device 57 removes charges of the quartz substrate 101 placed on the wafer stocker 51 in the gate unit 50.

For example, at step S02 shown in FIG. 2, the controller 53 of the gate unit 50 sends a command to the neutralization device 57 for removing the charges of the quartz substrate 101 on the wafer stocker 51 before reducing pressure in the gate unit 50. Specifically, for example, the quartz substrate 101 is irradiated with a soft X-ray emitted from the neutralization device 57. Subsequently, the step S03 and the subsequent steps in FIG. 2 are executed.

The soft X-ray emitted from the neutralization device generates the ionized atoms in the atmosphere, which neutralizes the charges of the quartz substrate 101. Thereby, variations in the dose amount of electrons due to a potential distribution in the quartz substrate 101 may be reduced. Further, it becomes possible to suppress a displacement of the irradiated position in the quartz substrate 101, when being selectively irradiated with the electron beam.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A multi-processing apparatus comprising:
an electron beam irradiation unit;
a dry etching unit; and
a transferring unit connected to the electron beam irradiation unit and the dry etching unit, the transferring unit being configured to transfer a wafer under a reduced-pressure atmosphere from the electron beam irradiation unit to the dry etching unit.

2. The multi-processing apparatus according to claim 1, wherein the electron beam irradiation unit is electrically insulated from the transferring unit.

3. The multi-processing apparatus according to claim 1, further comprising an isolation wall between the electron beam irradiation unit and the transferring unit, the isolation wall including a dielectric material.

4. The multi-processing apparatus according to claim 1, further comprising:
a controller sending control commands to the electron beam irradiation unit and the dry etching unit; and
a communication module provided between the controller and the electron beam irradiation unit, the communication module transmitting and receiving the control commands via optical signals.

5. The multi-processing apparatus according to claim 1, further comprising a plasma irradiation unit connected to the transferring unit.

6. The multi-processing apparatus according to claim 5, further comprising a controller programmed to irradiate the wafer with an electron beam in the electron beam irradiation unit after exposing the wafer to plasma in the plasma irradiation unit.

7. The multi-processing apparatus according to claim 1, wherein the transferring unit transfers the wafer in a reduced-pressure atmosphere at 10 Pa or less.

8. The multi-processing apparatus according to claim 1, wherein the transferring unit transfers the wafer in an atmosphere containing oxygen with a concentration of 20 ppm or less.

9. The multi-processing apparatus according to claim 1, wherein the electron beam irradiation unit holds the wafer at a predetermined temperature in a temperature range from −40° C. to 290° C.

10. The mufti-processing apparatus according to claim 1, wherein the electron beam irradiation unit holds the wafer at a predetermined potential.

11. The multi-processing apparatus according to claim 1, wherein the electron beam irradiation unit includes at least one of a heater and a cooling device.

12. The multi-processing apparatus according to claim 1, wherein the electron beam irradiation unit includes an oxygen concentration monitor.

13. The multi-processing apparatus according to claim 1, further comprising a gate unit connected to the transferring unit, the gate unit including a neutralization device that removes charges of the wafer.

14. The multi-processing apparatus according to claim 1, further comprising a temperature adjustment unit holding the wafer at a predetermined temperature.

15. A method for manufacturing a semiconductor device comprising:
irradiating a resist film formed on a wafer with an electron beam; and
dry-etching the wafer using the resist film,
the irradiating and the dry-etching being continuously performed under a reduced-pressure atmosphere.

16. The method according to claim 15, further comprising exposing the resist film to plasma before irradiating the resist film with the electron beam,
wherein the wafer is continuously treated under the reduced-pressure atmosphere through the irradiating, the dry-etching, and the exposing.

17. The method according to claim 15, further comprising removing charges of the wafer before the irradiating the wafer with the electron beam.

18. The method according to claim 15, wherein the wafer is irradiated with the electron beam under a condition, and over half of electrons are stopped in a surface layer of the resist film.
